(19) United States
(12) Patent Application Publication
(10) Pub. No.: US 2011/0244200 A1
(43) Pub. Date: Oct. 6, 2011

(54) Decorative Film And Method For Manufacturing The Same

(76) Inventors: Wilhelmus Josephus Alex Van De Wall, Heeze (NL); Hendrikus Hubertus Gerardus Voncken, Elsloo (NL)

(21) Appl. No.: 13/131,913

(22) PCT Filed: Nov. 30, 2009
(86) PCT No.: PCT/NL09/00238

§ 371 Date: Jun. 23, 2011

(30) Foreign Application Priority Data
Dec. 1, 2008 (NL) 1036259

(51) Int. Cl. B32B 3/00; B05D 1/38; C23C 14/28

(52) U.S. Cl. 428/201; 427/258; 427/511

(57) ABSTRACT

The present invention relates to a decorative film comprising a substrate, an intermediate layer, a decorative layer and a protective layer, respectively. The present invention further relates to a method for manufacturing a decorative film comprising a substrate, an intermediate layer, a decorative layer and a protective layer, respectively. The object of the present invention is to provide a decorative film which is suitable for outdoor use without any objectionable loss of the aesthetic value of the print in the decorative film. Another object of the present invention is to provide a decorative film in which the print present on the decorative film can be adapted as needed.

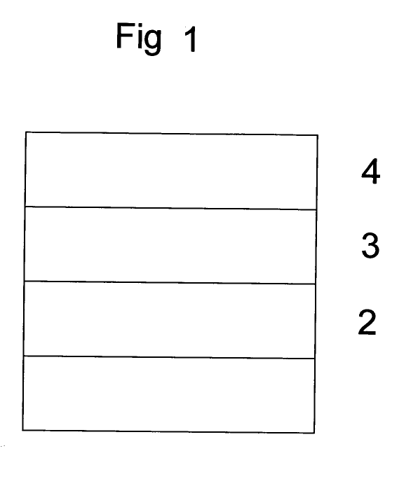

The present invention relates to a decorative film comprising a substrate, an intermediate layer, a decorative layer and a protective layer, respectively. The present invention further relates to a method for manufacturing a decorative film comprising a substrate, an intermediate layer, a decorative layer and a protective layer, respectively.

Decorative films are used for decorating plate materials, which plate materials are based mainly on resin-impregnated wood fibres. Such a decorative panel is known from U.S. Pat. No. 3,789,604 and U.S. Pat. No. 4,801,495 in the name of the present applicant. The decorative films known from said U.S. patents are given a structured surface by using a polyester or polypropylene film. Such decorative films are further passed between two rollers, during which passage the structure present on the roller surface is transferred to the decorative film, which means that a repetitive pattern corresponding to the pattern present on the outer surface of the roller(s) will form on the decorative film.

The object of the present invention is to provide a decorative film which is suitable for outdoor use, with a durable bond between the individual layers and without any objectionable loss of the aesthetic value of the print in the decorative film.

Another object of the present invention is to provide a decorative film in which the print in the decorative film can be adapted as needed.

Yet another object of the present invention is to provide a decorative film which exhibits a high degree of colour fastness, wherein the plate material on which the decorative film is present is resistant to weather influences such as sunlight and rainfall.

According to the invention, the decorative film as described in the first paragraph is characterised in that the decorative layer is a layer formed by means of inkjet technology.

One or more of the above objects can be accomplished by using a layer applied by means of inkjet technology as the decorative layer, which decorative layer preferably comprises pigments, radiation-curable and/or heat-curable components. Although a method for using inkjet technology for manufacturing decorative films is known from European patent publication EP 1 923 223, it is not known from said publication to provide the substrate layer, which is usually a paper-based layer, with an intermediate layer, which intermediate layer prevents the layer that has been formed by means of inkjet technology from being absorbed into the paper layer on account of the capillary action of the paper itself, which would cause the intended print to become blurred.

It is in particular desirable for the pigments to be selected from organic and inorganic pigments, with the percentage of inorganic pigments amounting to at least 10 wt. %, based on the total weight of pigments, whilst more in particular the inkjet-applied layer does not cover the intermediate layer entirely. At least one of the inorganic pigments has been selected from the group consisting of pigment yellow 42, pigment yellow 53, pigment yellow 184, pigment yellow 157, pigment yellow 161 and pigment brown 24. Combinations of various inorganic pigments from the above group are also possible. If the percentage of inorganic pigments is less than 10 wt. %, the resistance to weather influences will be too low. The presence of such inorganic pigments in the decorative layer can be determined by means of crystallography, for example. The inorganic pigments preferably used in the present decorative layer have a density of >3 kg/l and contain particles having a particle size of >100 nm.

The use of pigments in an inkjet-applied decorative layer makes it possible to impart one or more functionalities to the decorative layer. Possible pigments include organic pigments, inorganic pigments, luminescent pigments and effect pigments, such as pigments based on aluminium, mica, flakes, luster, leafing, non-leafing and crystals. The inkjet technology makes it possible in particular to apply the pigment-containing layer only to part of the surface, for example in so-called dots or discrete islands, thus realising a considerable saving on ink costs. Functionalities that may be incorporated in the decorative film include UV absorption, UV reflection, IR absorption, IR reflection, fluorescence, light stabilisation, antistaticity, fire-resistance, gloss degree adjustment, polarisation, reflection and the like. In a preferred method, the decorative film consists of a set of inks formulated in low-viscosity reactive diluents (such as TPGDA), in which weather-resistant pigments are dispersed. To impart stability to the aforesaid dispersion, dispersants are preferably added. The dispersion may also comprise UV initiators so as to enable UV curing of the dispersion. The viscosity of the decorative layer is much lower than that of the intermediate layer and the protective layer, because the decorative layer must be applied by means of inkjet heads, which technology requires a low viscosity. Because of the required chemistry, the resulting ink formulation for the decorative layer is less resistant to mechanical loads and radiation with light than the intermediate layer and the protective layer.

The decorative film used in the present application comprises a substrate, in particular selected from the group consisting of a resin-impregnated paper and a resin-impregnated non-woven, possible resins being: phenol resin, melamine resin, urethane-, polyester- and epoxy groups-containing resins, (meth)acrylate, or combinations thereof.

The present decorative film also comprises an intermediate layer, which intermediate layer comprises radiation-curable components selected from the group of electron beam-curable resins and UV-curable resins. The intermediate layer is applied over the entire substrate surface area. The composition of the intermediate layer is such that the inkjet-applied decorative layer present on the intermediate layer cannot permeate into the substrate. The inkjet layer as the decorative layer thus retains its configuration and structure as originally applied. The provision of such an intermediate layer is in particular desirable if a substrate which exhibits capillary action is used; in particular a fibre-containing substrate, such as paper. The intermediate layer preferably contains aliphatic urethane groups. The intermediate layer also makes it possible to realise a durable bond between the decorative layer and the substrate. A few of the intermediate layer's function comprise the creation of a closed and smooth layer on the substrate, which can be printed with the highest picture definition and colour intensity, and the creation of a bonding surface for the decorative layer. In a preferred embodiment, the intermediate layer is pigmented so as to thus realise a defined colour, by means of which the colour of the underlying substrate is masked. A white intermediate layer, pigmented with titanium dioxide, is desirable. Optionally, fire retardants may be incorporated in the intermediate layer. Optionally, the intermediate layer serves to protect the substrate against the action of light on the photosensitive substrate. For said protection, substances which need not be transparent of colourless may be used, such as titanium dioxide, for example. If the intermediate layer contains pigments, an intermediate layer having a unicolor will be realised on the substrate layer. In a preferred method, the intermediate layer consists of an aliphatic urethane acrylate, which has been diluted to processing viscosity by means of HDDA as the reactive diluent and which has been provided with titanium dioxide so as to protect the substrate against light and give the intermediate layer a defined white colour.

A transparent layer is used as the protective layer, which transparent layer comprises radiation-curable components, which components are selected from the group of electron beam-curable resins and UV-curable resins, whilst in particular stabilisers are present, which are selected from the group of UV absorbers and Hindered Amine Light Stabilisers (HALS). Resins which are in particular suitable are resins that contain aliphatic urethane groups. The protective layer is provided with additives which protect the substrate, the intermediate layer and the decorative layer against the influence of light. Because the protective layer must not adversely affect the visually attractive image formed by the joint underlying layers, the protective layer is preferably colourless and practically transparent. The protective layer protects the underlying layers against scratching, wear and chemical attack. The protective layer may optionally make the final product easier to clean and give the final product a uniform degree of gloss and (micro)structure. The protective layer may furthermore make the surface antistatic or electro-dissipative.

In a preferred method, the protective layer consists of a layer of aliphatic urethane acrylates, which have been diluted to processing viscosity by means of HDDA as the reactive diluent. Furthermore, HALS stabilisers and UV absorbers may have been added.

The composition of the protective layer is such that the protective layer is transparent and resistant to moisture and UV radiation. The decorative layer, on the other hand, contains pigments, which are preferably brightly coloured and at least partially transparent. In addition to that, the intermediate layer optionally contains pigments, preferably in a white or light colour, and protects the substrate against the inkjet-applied layer.

The present invention further relates to a method for manufacturing the present decorative film, which method comprises the following steps:
i) providing a substrate,
ii) applying the intermediate layer to the substrate,
iii) forming a decorative layer on the intermediate layer by means of inkjet technology,
iv) applying a protective layer, followed by the curing of the assembly i)-iv).

In a special embodiment, the assembly consisting of substrate and intermediate layer is subjected to a curing treatment prior to the application of the decorative layer by means of inkjet technology. In a special embodiment, it is furthermore preferable to subject the assembly consisting of substrate, intermediate layer and decorative layer to a curing treatment prior to the application of the protective layer. More in particular, the assembly consisting of substrate and intermediate layer and decorative layer is cured to such a degree after completion of step ii) that complete curing does not take place. Specially that the assembly consisting of substrate, intermediate layer and decorative layer is cured to such a degree after completion of step iii) that complete curing does not take place. It is furthermore desirable that the protective layer be treated with short wavelength UV radiation from a radiation source, in particular radiation having a wavelength in the 100-250 nm range, after completion of step iv). In a special embodiment, the assembly of substrate, intermediate layer, decorative layer and protectively layer is subjected to a pre-curing step after completion of step iv), whereupon the exposed surface of the protective layer is provided with a microstructure by means of a mechanical operation, in particular by placing a press on the aforesaid exposed surface, whereupon curing takes place, whilst a film is applied to the exposed surface of the protective layer after completion of step iv), which film transmits the radiation used in the curing step.

Another embodiment for manufacturing the present decorative film comprises the following steps:
i) providing a film,
ii) applying a protective layer to the film,
iii) providing a substrate,
iv) applying an intermediate layer to the substrate,
v) forming an inkjet layer on the intermediate layer,
vi) joining the assembly obtained after step ii) and the assembly obtained after step v) together, followed by the curing thereof.

In a special embodiment of such a method it has been found to be possible to subject the assembly of film and protective layer prematurely to a curing treatment, whereupon the assembly thus cured is contacted with the assembly consisting of substrate, intermediate layer and inkjet layer so as to form the intended decorative film. It is also possible, however, to cure the assembly consisting of substrate, intermediate layer and inkjet layer in advance, whereupon the assembly thus cured is contacted with the film provided with a protective layer so as to obtain the intended decorative film.

Yet another method for manufacturing the present film comprises the steps of:
i) providing a film,
ii) applying a protective layer to the film,
iii) forming an inkjet layer on the protective layer,
iv) providing a substrate,
v) applying an intermediate layer to the substrate,
vi) joining the assembly obtained after step iii) and the assembly obtained after step v) together, followed by the curing thereof.

In such a method it is moreover possible to cure the assembly obtained after step iii) and/or the assembly obtained after step v) prior to carrying out step vi).

Special embodiments of the present methods are defined in the appended claims.

The present invention further relates to a method for manufacturing a decorative panel, comprising the steps of applying the present decorative film to at least one surface side of a core layer and subsequently pressing the same together at an elevated temperature and pressure. A suitable core layer material will be a material from the group consisting of wood, a number of paper sheets, plastic or metal, non-woven and fibre mats. Phenol formaldehyde resin-impregnated paper layers can be used as said paper sheets, in particular kraft paper sheets. The present invention relates to a decorative film in which the inorganic pigments have a density >3 kg/l and contain particles having a particle size >100 nm.

The appended FIGURE schematically shows a decorative film according to the present invention, in which the substrate 1 is provided with an intermediate layer 2, which intermediate layer 2 is provided with an inkjet-applied decorative layer 3, which decorative layer 3 is provided with a protective layer 4.

The present invention will be explained in more detail hereinafter by means of a number of examples, in which connection it should be noted, however, that the present invention is by no means limited to such examples.

### EXAMPLE 1

An intermediate layer, consisting of 50% Ebecryl 284, 20% HDDA, 30% Kronos 2220 is applied to a paper substrate impregnated with a phenol-resol-resin. A 30 micron polyester film is applied to said wet layer. The whole is cured by means of electron radiation (10 kGray, 225 kV). Following the removal of the polyester film from this laminate, an ink, type Coates Jet 5529, cyano, is applied in a thickness of 12 micron to the thus cured intermediate layer, using inkjet technology, and cured with UV. Then a 30 micron protective layer consisting of 70% Ebecryl 284 and 30% HDDA is applied. The whole is subsequently cured by means of electron radiation (60 kGray, 225 kV). In this way a decorative film is obtained, which is subsequently pressed onto a stack of phenol resin-impregnated papers to form an HPL compact laminate (20 min, 160° C., 90 Bar).

### EXAMPLE 2

An intermediate layer consisting of 49% Ebecryl 284, 20% HDDA, 30% Kronos 2220, 1% Tinuvin 292 is applied to a paper substrate impregnated with a phenol-resol-resin. A 30 micron polyester film is applied to this wet layer. The whole is cured by means of electron radiation (10 kGray, 225 kV). Following the removal of the polyester film, an ink (Coates) is applied, using inkjet technology, and cured with UV. Suitable inks include Coates Jet 5529, cyano, 15 micron, U2103-11.7.00, magenta, 15 micron, Coates Jet 7537, FP02715, black Coates Jet 1532WO70226, yellow. A 30 micron protective layer consisting of 68% Ebecryl 284, 1% Tinuvin 400, 1% Tinuvin 292 and 30% HDDA is coated onto said layer. The whole is subsequently cured, using electron radiation (60 kGray, 225 kV). In this way a decorative film is obtained, which is subsequently pressed onto a stack of phenol resin-impregnated papers to form an HPL compact laminate (20 min, 160° C., 90 Bar).

### EXAMPLE 3

An intermediate layer consisting of 50% Ebecryl 284, 20% HDDA, 30% Kronos 2220 is applied to a paper substrate impregnated with a phenol-resol-resin. The whole is cured in air, using electron radiation (10 kGray, 225 kV). Following that, an ink (Scitex) is applied by means of inkjet technology and subsequently dried. A 30 micron protective layer consisting of 68% Ebecryl 284, 1% Tinuvin 400, 1% Tinuvin 292 and 30% HDDA is coated onto said ink. The whole is subsequently cured by means of electron radiation (60 kGray, 225 kV). In this way a decorative film is obtained, which is subsequently pressed onto a stack of phenol resin-impregnated papers to form an HPL compact laminate (20 min, 160° C., 90 Bar).

### EXAMPLE 4

An intermediate layer consisting of 49% Ebecryl 284, 20% HDDA, 30% Kronos 2220, 1% Tinuvin 292 is applied to a paper substrate impregnated with a phenol resol resin. A 30 micron polyester film is coated onto said wet coating layer. The whole is cured by means of electron radiation (10 kGray, 225 kV). Following the removal of the polyester film, a water-based ink containing inorganic pigments (Toyo-ink) is applied, using inkjet technology, and subsequently cured. A 30 micron protective layer consisting of 68% Ebecryl 284, 1% Tinuvin 400, 1% Tinuvin 292 and 30% HDDA is coated onto said layer. The whole is subsequently cured by means of electron radiation (60 kGray, 225 kV). In this way a decorative film is obtained, which is subsequently pressed onto a stack of phenol resin-impregnated papers to form an HPL compact laminate (20 min, 160° C., 90 Bar).

### EXAMPLE 5

An intermediate layer consisting of 49% Ebecryl 284, 20% HDDA, 30% Kronos 2220, 1% Tinuvin 292 is applied to a decorative paper impregnated with an aqueous dispersion of a radiation-curable acrylate. The CMYK-inks for the Anapurna M of AGFA Graphics are applied to said wet coating layer by means of an inkjet printer. A 30 micron protective layer consisting of 68% Ebecryl 284, 1% Tinuvin 400, 1% Tinuvin 292 and 30% HDDA is coated onto said inks in combination with a 30 micron polyester film. The whole is subsequently cured by means of electron radiation (60 kGray, 225 kV). In this way a decorative film is obtained, which is subsequently pressed onto a stack of phenol resin-impregnated papers to form an HPL compact laminate (20 min, 160° C., 90 Bar). The yellow pigment in this type of ink was substituted for an inorganic yellow pigment.

### EXAMPLE 6

A 30 micron protective layer consisting of 68% Ebecryl 284, 1% Tinuvin 400, 1% Tinuvin 292 and 30% HDDA is coated onto a 60 micron polyester film and subsequently cured by means of electron radiation (6 kGray, 225 kVolt). The CMYK-inks for the Anapurna M of AGFA Graphics are applied to said layer by means of an inkjet printer and cured with UV. An intermediate layer consisting of 49% Ebecryl 284, 20% HDDA, 30% Kronos 2220, 1% Tinuvin 292 is applied to a paper substrate impregnated with an aqueous dispersion of a radiation-curable acrylate. The film with the protective layer present thereon is laminated onto the wet intermediate layer and subsequently cured by means of electron radiation (60 kGray, 225 kV). In this way a decorative film is obtained, which is subsequently pressed onto a stack of phenol resin-impregnated papers to form an HPL compact laminate (20 min, 160° C., 90 Bar). The yellow pigment as well as the red pigment in this ink set were substituted for an inorganic pigment.

A good adhesion of the ink to the intermediate layer was measured both with the cross-hatch test and with the boiling test. The colour fastness of all the colours is better than grey scale 4, assessed in accordance with EN 20105-A02, after a weather resistance test in accordance with EN 438-2:2005, chapter 29.

### EXAMPLE 7

An intermediate layer consisting of 49% Ebecryl 284, 20% HDDA, 30% Kronos 2220, 1% Tinuvin 292 is applied to a paper substrate impregnated with a phenol resol resin. A 30 micron polyester film is applied to this wet layer. The whole is cured by means of electron radiation (30 kGray, 225 kV). Following the removal of the polyester film, special CMYK inks for the Anapurna M of AGFA Graphics are applied with the Anapurna M, using inkjet technology, and cured with UV. A 30 micron protective layer consisting of 65% Ebecryl 284, 1% Tinuvin 400, 1% Tinuvin 292, 3% Darocur 1173 and 30% HDDA is coated onto said inks. The whole is subsequently cured, using UV radiation (60 kGray, 225 kV). In this way a decorative film is obtained, which is subsequently pressed onto a stack of phenol resin-impregnated papers to form an HPL compact laminate (20 min, 160° C., 90 Bar). The yellow pigment in this ink set was substituted for an inorganic yellow pigment.

A good adhesion of the ink to the intermediate layer was measured both with the cross-hatch test and with the boiling test. The colour fastness of all the colours is better than grey scale 4, assessed in accordance with EN 20105-A02, after a weather resistance test in accordance with EN 438-2:2005, chapter 29.

### COMPARATIVE EXAMPLE 1

A decorative layer is formed on a substrate of a white decorative paper coloured with titanium dioxide impregnated with a melamine resin, using the CMYK inks for the Anapurna M of AGFA-graphics and an inkjet-printer. The inks are cured with UV prior to the formation of a 30 micron protective layer consisting of 68% Ebecryl 284, 1% Tinuvin 400, 1% Tinuvin 292 and 30% HDDA on top of said decorative layer. The whole is cured by means of electron radiation (60 kGray, 225 kV). In this way a decorative film is obtained, which is subsequently pressed onto a stack of phenol resin-impregnated papers to form an HPL compact laminate (20 min, 160° C., 90 Bar). The image quality of the decorative layer is too low, because part of the ink has run out into the substrate due to the absence of an intermediate layer. The colour fastness of this laminate is distinctly worse than grey scale 1, assessed in accordance with EN 20105-A02, after a weather resistance test in accordance with EN 438-2:2005, chapter 29. The protective layer was damaged during the weather resistance test.

### COMPARATIVE EXAMPLE 2

A 30 micron protective layer consisting of 68% Ebecryl 284, 1% Tinuvin 400, 1% Tinuvin 292 and 30% HDDA is coated onto a 60 micron polyester film. This proactive layer is subsequently cured by means of electron radiation (6 kGray, 225 kVolt). A decorative layer is formed on said layer, using an inkjet printer and the CMYK-inks for the Anapurna M of AGFA. This decorative layer is subsequently cured with UV. Following that, an intermediate layer of 100 micron consisting of 49% Ebecryl 284, 20% HDDA, 30% Kronos 2220, 1% Tinuvin 292 is applied to a paper substrate impregnated with phenol resin. The previously obtained polyester film with the fixed protective layer and the decorative layer is laminated onto said wet intermediate layer, and subsequently the whole is cured by means of electron radiation (60 kGray, 225 kV). In this way a decorative film is obtained, which is subsequently pressed onto a stack of phenol resin-impregnated papers to form an HPL compact laminate (20 min, 160° C., 90 Bar). In this ink set only the red pigment was substituted for an inorganic pigment. A good adhesion of the ink to the intermediate layer was measured both with the cross-hatch test and with the boiling test. The colour fastness of this laminate is distinctly worse than grey scale 1, assessed in accordance with EN 20105-A02, after a weather resistance test as described in EN 438-2:2005, chapter 29. The yellow organic ink thus loaded exhibited serious fading, resulting in an unacceptable difference in colour with the original, which original was not subjected to the weather resistance test.

1. A decorative film comprising a substrate, an intermediate layer, a decorative layer and a protective layer, respectively, wherein said decorative layer is a layer formed by means of inkjet technology.

2. The decorative film according to claim 1, wherein said decorative layer comprises pigments, radiation-curable and/or heat-curable components.

3. The decorative film according to claim 2, wherein the pigments are selected from organic and inorganic pigments, with the percentage of inorganic pigments amounting to at least 10 wt. %, based on the total weight of pigments.

4. The decorative film according to claim 3, wherein at least one of the inorganic pigments has been selected from pigment yellow 42, pigment yellow 53, pigment yellow 184, pigment yellow 157, pigment yellow 161 and pigment brown 24.

5. The decorative film according to claim 1 wherein the inkjet-applied layer does not cover the intermediate layer entirely.

6. The decorative film according to claim 1 wherein the substrate has been selected from a resin-impregnated paper and a resin-impregnated non-woven.

7. The decorative film according to claim 6, wherein the resin has been selected from phenol resin, melamine resin, urethane-, polyester- and epoxy groups-containing resins, (meth)acrylate, or combinations thereof.

8. The decorative film according to claim 1 wherein the intermediate layer comprises radiation-curable components.

9. The decorative film according to claim 8, wherein said radiation-curable components have been selected from electron beam curable resins and UV-curable resins.

10. The decorative film according to claim 1, wherein the protective layer is transparent.

11. The decorative film according to claim 10, wherein the protective layer comprises radiation-curable components selected from electron beam-curable resins and UV-curable resins.

12. The decorative film according to claim 10 wherein the protective layer comprises stabilisers selected from UV absorbers and hindered amine light stabilizers.

13. A method for manufacturing a decorative film comprising a substrate, an intermediate layer, a decorative layer and a protective layer, respectively, wherein the method comprises the following steps: i) providing a substrate, ii) applying the intermediate layer to the substrate, iii) forming a decorative layer on the intermediate layer by means of inkjet technology, iv) applying a protective layer, followed by the curing of the assembly formed by steps i)-iv).

14. The method according to claim 13, wherein the substrate and intermediate layer are cured to such a degree after completion of step ii) that complete curing does not take place.

15. The method according to claim 13 wherein the substrate, intermediate layer and decorative layer are subjected to a curing step after completion of step iii), such that complete curing does not take place.

16. The method according to claim 13 wherein the protective layer is treated with short wavelength UV radiation from a radiation source, having a wavelength in the 100-250 nm range, after completion of step iv).

17. The method according to claim 13 wherein the substrate, intermediate layer, decorative layer and protectively layer are subjected to a pre-curing step after completion of step iv), whereupon the exposed surface of the protective layer is provided with a microstructure by means of a mechanical operation, by placing a press on the aforesaid exposed surface, whereupon curing takes place.

18. The method according to claim 13 wherein a film is applied to the exposed surface of the protective layer after completion of step iv), which film transmits the radiation used in the curing step.

19. A method for manufacturing a decorative film comprising a substrate, an intermediate layer, a decorative layer and a protective layer, respectively, wherein the method comprises the following steps: i) providing a film, ii) applying a protective layer to the film, iii) providing a substrate, iv) applying an intermediate layer to the substrate, v) forming an inkjet layer on the intermediate layer, vi) joining the assembly obtained after step ii) and the assembly obtained after step v) together, followed by the curing thereof.

20. The method according to claim 19, wherein the assembly obtained after step ii) and/or the assembly obtained after step v) is cured to such a degree prior to carrying out step vi) that complete curing does not take place.

21. A method for manufacturing a decorative film comprising a substrate, an intermediate layer, a decorative layer and a protective layer, respectively, wherein the method comprises the following steps: i) providing a film, ii) applying a protective layer to the film, iii) forming an inkjet layer on the protective layer, iv) providing a substrate, v) applying an intermediate layer to the substrate, vi) joining the assembly obtained after step iii) and the assembly obtained after step v) together, followed by the curing thereof.

22. The method according to claim 21, wherein the assembly obtained after step iii) and/or the assembly obtained after step v) is cured to such a degree prior to carrying out step vi) that complete curing does not take place.

23. A method for manufacturing a decorative panel, comprising the steps of applying a decorative film according to claim 1 to at least one surface side of a core layer and subsequently pressing the same together at an elevated temperature and pressure.

24. The method according to claim 23, wherein the film is removed from the decorative film either before or after said pressing together.

25. A decorative panel comprising a decorative film according to claim 1.

26. A decorative film according to claim 3 wherein the inorganic pigments have a density >3 kg/l and contain particles having a particle size >100 nm.
